(19) United States
(12) Patent Application Publication
(10) Pub. No.: US 2010/0255634 A1
(43) Pub. Date: Oct. 7, 2010

(54) Manufacturing method of bottom substrate of package

(75) Inventors: Jung-Hyun Park, Cheongju-si (KR); Byoung-Youl Min, Seongnam-si (KR); Je-Gwang Yoo, Yongin-si (KR); Myung-Sam Kang, Daejeon (KR); Hoe-Ku Jung, Daejeon (KR); Ji-Eun Kim, Gwangmyeong-si (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon (KR)

(21) Appl. No.: 12/801,574

(22) Filed: Jun. 15, 2010

Related U.S. Application Data
(62) Division of application No. 11/708,568, filed on Feb. 21, 2007.

(30) Foreign Application Priority Data
Jul. 6, 2006 (KR) 10-2006-0063633

(51) Int. Cl. H01L 21/60; H01L 21/50

(52) U.S. Cl. 438/107; 438/121; 257/E21.499; 257/E21.509

(57) ABSTRACT

A manufacturing method of bottom substrate of package. A bottom substrate of a package on package electrically connected to a top substrate by means of a solder ball, including a core board, a solder ball pad formed on a surface of the core board in correspondence with a location of the solder ball, an insulation layer laminated on the core board, a through hole formed by removing a part of the insulation layer such that the solder ball pad is exposed, and a metallic layer filled in the through hole and connected electrically with the solder ball, allows the number of ICs mounted on a bottom substrate to be increased without increasing the size of a solder ball, and allows the size and pitch of the solder balls to be made smaller by controlling the thickness of the insulation layer laminated on the bottom substrate, whereby more signal transmission is possible between a top substrate and a bottom substrate.

### CROSS-REFERENCE TO RELATED APPLICATIONS

This application is a U.S. divisional application filed under 35 USC 1.53(b) claiming priority benefit of U.S. Ser. No. 11/708,568 filed in the United States on Feb. 21, 2007, which claims earlier priority benefit to Korean Patent Application No. 10-2006-0063633 filed with the Korean Intellectual Property Office on Jul. 6, 2006, the disclosures of which are incorporated herein by reference.

### BACKGROUND OF THE INVENTION

1. Field

The present invention relates to a bottom substrate of a package on package and a manufacturing method thereof.

2. Description of the Related Art

With developments in the electronics industry, there are requests for high performance, high density and miniaturization for electronic components. In order to meet these requests, there is a growing number of proposals and demands for realizing the so called ‘package substrate’ manufactured by mounting electronic devices such as ICs on printed circuit boards, where the so called ‘package on package (POP)’ manufactured by laminating another package substrate on a package substrate is gaining attention as a good alternative among methods for implementing a package substrate.

As to a POP, in a trend of mounting one electronic device on a substrate in order to correspond with the demand of higher-end and higher density products, the so called ‘stack package’ manufactured by piling up several electronic devices on a substrate has appeared.

The overall thickness of a package is important in the process of implementing a POP, and from a trend of mounting one IC on a substrate, the demand of mounting two or more ICs on a substrate has been generated in order to make a POP more high-end. However, this approach reached a limit in realizing a POP, because the total thickness of a package increased in the case of mounting two or more ICs on a substrate.

As to the conventional structure of a POP, an IC is mounted on the surface of a bottom substrate located below. The bottom substrate is manufactured by the general manufacturing method for a printed circuit board. As described in the above, there is a demand for the multi-stack, in which two or more ICs are mounted, but it is difficult to increase the number of ICs mounted on a bottom substrate while maintaining the overall height of a POP by conventional manufacturing methods.

To this, by applying the so-called ‘Die Thinning’ method by which an IC chip is cut except for the necessary part, every effort has been made to solve the above problem. However, with the occurrence of the function-error generated when operating for a long period of time the IC chip to which the method has been applied, attempts have been made to rather reduce the substrate thickness so as to raise the mount capability of POP and implement the multi stack.

Also, in the conventional POP, in the case of manufacturing an IC thinner, in order to stack two or more ICs on a bottom substrate, problems in handling, and warpage, etc. are caused.

Moreover, by not thinning the IC but by growing the size of the solder balls which connect a top package to a bottom package electrically, the gap between packages can be increased. However, as the number of ICs stacked is increased, increasing the number of solder balls poses limits in designing the number of and intervals between solder ball pads.

### SUMMARY

Aspects of the present invention provide a bottom substrate of a package on package and manufacturing method thereof that ensures the gap between packages such that two or more electronic devices can be mounted on a bottom substrate without increasing the overall thickness, to implement a POP.

One aspect of the present invention provides a bottom substrate of a package on package electrically connected to a top substrate by means of a solder ball, which includes a core board, a solder ball pad formed on a surface of the core board in correspondence with a location of the solder ball, an insulation layer laminated on the core board, a through hole formed by removing a part of the insulation layer such that the solder ball pad is exposed, and a metallic layer filled in the through hole and connected electrically with the solder ball.

The insulation layer may be formed by laminating photoresist on the core board and hardening through heating.

An electronic device may be mounted on the bottom substrate, and the bottom substrate may further comprise a bonding pad formed on the core board and connected electrically to the electronic device, and a cavity formed by removing a part of the insulation layer such that the bonding pad is exposed.

Another aspect of the present invention provides a package on package comprising a core board, a solder ball pad and a bonding pad formed on the surface of the core board, an insulation layer laminated on the core board, a through hole formed by removing a part of the insulation layer such that the solder ball pad is exposed, a metallic layer filled in the through hole, a solder ball connected electrically to the metallic layer, a cavity formed by removing a part of the insulation layer such that the bonding pad is exposed, an electronic device mounted on the cavity, and connected electrically with the bonding pad, and a top substrate joined with the core board to cover the electronic device and connected electrically with the solder ball.

The insulation layer may be formed by laminating photoresist on the core board and hardening through heating.

Still another aspect of the present invention provides a method of manufacturing a bottom substrate of a package on package connected electrically with a top substrate by a solder ball, which includes (a) forming a solder ball pad on the surface of a core board in correspondence with a location of the solder ball, (b) laminating an insulation layer on the core board, (c) forming a through hole by removing a part of the insulation layer such that the solder ball pad is exposed, and (d) filling a metallic layer in the through hole.

The operation (a) may further comprise spreading solder resist on the surface of the core board.

An electronic device may be mounted on the bottom substrate, and the operation (a) may comprise forming a bonding pad connected electrically with the electronic device on the surface of the core board, and the operation (c) may comprise forming a cavity by removing a part of the insulation layer such that the bonding pad is exposed.

The insulation layer may comprise photoresist, and the operation (c) may comprise selective exposure and development of the insulation layer. The method may further comprise (h) hardening the insulation layer by applying heat, between the operation (c) and the operation (d).

The method may further comprise spreading photoresist on the cavity between the operation (h) and the operation (d). The operation (d) may be performed by forming a plating layer on the solder ball pad by supplying electricity. The method may further comprise removing the photoresist spread on the cavity after the operation (d).

Another aspect of the present invention provides a method of manufacturing a package on package, which includes (a) forming a solder ball pad and a bonding pad on a surface of a core board, (b) laminating an insulation layer on the core board, (c) forming a through hole by removing a part of the insulation layer such that the solder ball pad is exposed, and forming a cavity by removing a part of the insulation layer such that the bonding pad is exposed, (d) filling a metallic layer in the through hole, (e) mounting an electronic device on the cavity to be connected electrically with the bonding pad, (f) joining a solder ball with the metallic layer, and (g) joining a top substrate with the core board to cover the electronic device and to be connected electrically with the solder ball.

The operation (a) may comprise spreading solder resist on the surface of the core board. The insulation layer may comprise photoresist, and the operation (c) may comprise selective exposure and development of the insulation layer.

The method may further comprise (h) hardening the insulation layer by applying heat, between the operation (c) and the operation (d). The method may further comprise spreading photoresist on the cavity between the operation (h) and the operation (d). The operation (d) may be performed by forming a plating layer on the solder ball pad by supplying electricity.

The method may further comprise removing the photoresist spread on the cavity between the operation (d) and the operation (e).

Additional aspects and advantages of the present invention will be set forth in part in the description which follows, and in part will be obvious from the description, or may be learned by practice of the present invention.

### BRIEF DESCRIPTION OF THE DRAWINGS

FIG. 1 is a cross-sectional view illustrating an embodiment of a bottom substrate of package on package according to the present invention.

FIG. 2 is a flow chart illustrating an embodiment of manufacturing method of a bottom substrate of package on package according to the present invention.

FIG. 3 is a flow diagram illustrating an embodiment of manufacturing process of a bottom substrate of package on package according to the present invention.

FIG. 4 is a flow chart illustrating another embodiment of manufacturing method of a bottom substrate of package on package according to the present invention.

FIG. 5 is a cross-sectional view illustrating an embodiment of a package on package according to the present invention.

### DETAILED DESCRIPTION OF THE EMBODIMENTS

Certain embodiments of the present invention will be described below in more detail with reference to the accompanying drawings. In the description with reference to the accompanying drawings, those components are rendered the same reference number that are the same or are in correspondence regardless of the figure number, and redundant explanations are omitted.

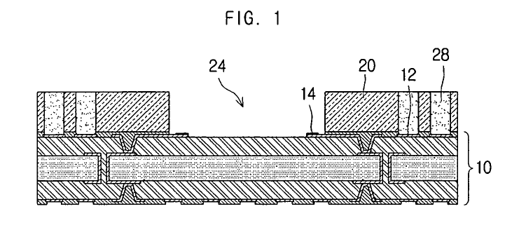

FIG. 1 is a cross-sectional view illustrating an embodiment of a bottom substrate of package on package according to the present invention. Referring to FIG. 1, a core board 10, solder ball pads 12, bonding pads 14, an insulation layer 20, a cavity 24, and a metallic layer 28 are illustrated.

The present embodiment is characterized by manufacturing the core board 10 of a bottom substrate having a layer or multi-layers of a circuit pattern formed by a conventional method of manufacturing a printed circuit board, and then ensuring the gap between packages by interposing the insulation layer 20 formed by hardening a photoresist and metallic layer 28 formed by plating the part of solder ball pad 12 between the packages, so that more electronic devices can be mounted on the bottom substrate.

The bottom substrate of a POP according to the present embodiment is the substrate used in a POP that is connected electrically with a top substrate by a solder ball. In the following, the substrate used for a bottom package is referred to as the ‘bottom substrate’, and the substrate used for a top package is referred to as the ‘top substrate’, but the ‘top substrate’ and ‘bottom substrate’ is not certainly restricted to the location of the upper or lower part, and the bottom substrate may be located in the upper part and the top substrate may be located in the lower part, within the range that the POP is manufactured in the same structure as that of the present embodiment.

The bottom substrate of a POP according to the present embodiment is formed by laminating the insulation layer 20 on the core board 10 to ensure more space from the top substrate. The insulation layer 20 is laminated with the thickness covering the height of the electronic device mounted on a bottom substrate. As described above, if the height of the electronic device mounted on a bottom substrate is only covered by the size of a solder ball, the size of the solder balls also increases as the number of electronic device mounted is increased, imposing greater restrictions in design.

In the present embodiment, a solder ball for electrical connection between packages is joined with the insulation layer 20, and the solder ball pad 12 formed on the surface of the core board 10 corresponding to the location of the solder ball is exposed by forming a through hole by removing the corresponding part of the insulation layer 20 laminated. In the through hole, as is explained in the following, a metallic layer 28 is filled through plating, and the electrical connection to the solder ball is realized.

In the bottom substrate, the bonding pad 14 connected electrically with an electronic device is formed on which to mount the electronic device. The solder ball pad 12 and the bonding pad 14 described above may be formed in separate processes respectively, or may be formed as a part of a circuit pattern in the course of forming the circuit pattern on the core board 10.

In order to mount an electronic device, the cavity 24 is formed in the insulation layer 20 laminated on the core board 10 by removing the corresponding part of the insulation layer 20, such that the portion where the electronic device is to be mounted, i.e. the portion where the bonding pad 14 is formed, is exposed. By forming the cavity 24 in the insulation layer 20 and mounting the electronic device, instead of mounting an electronic device on a bottom substrate and connecting electrically with a top substrate using a solder ball, the space corresponding to the thickness of the insulation layer 20, that is, the depth of the cavity 24, is acquired, so that more electronic devices can be mounted. In this way, without increasing the size of the solder balls, by controlling the thickness of the insulation layer 20, a sufficient gap is ensured between a bottom substrate and a top substrate.

Since the parts of the solder ball pad 12 and the bonding pad 14 are to be removed selectively after the insulation layer 20 is laminated on the core board 10, it is preferable that a photo-sensitive material be included that is applicable to exposure, development and etching processes. The insulation layer 20 may include materials whose properties can be changed, so that it is not removed in the following etching process, after the necessary parts have been selectively removed. For example, in the case that photoresist is laminated on the core board 10 as the material of the insulation layer 20, after forming the through hole and the cavity 24 through exposure, development and etching, the insulation layer 20 can be made not to be removed in the following etching process by applying infrared radiation or heat to harden the insulation layer 20.

For the material that is applicable to exposure and development, and can be used as insulation material by hardening, generally used materials such as ‘FR-4’, ‘BT resin’, etc. can be used, as well as materials having a double joining structure as in the following chemical formula (1).

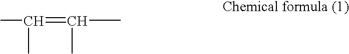

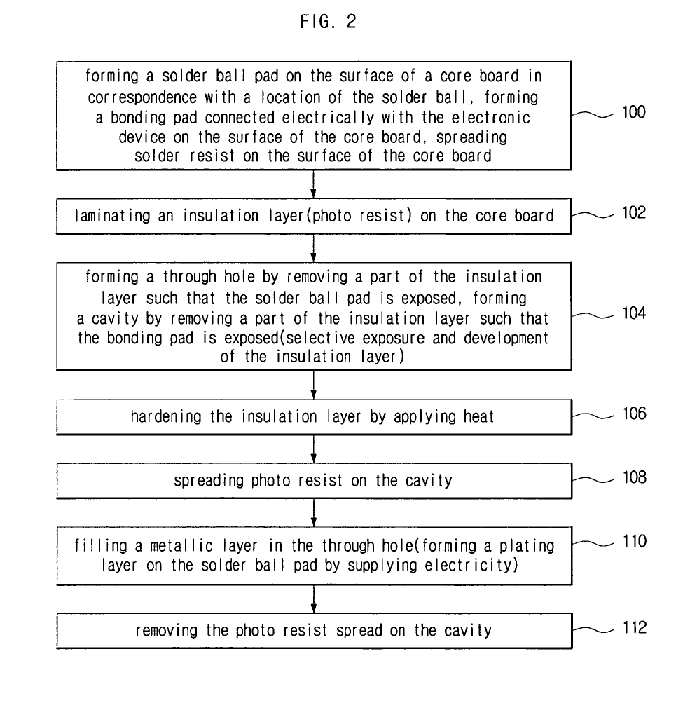

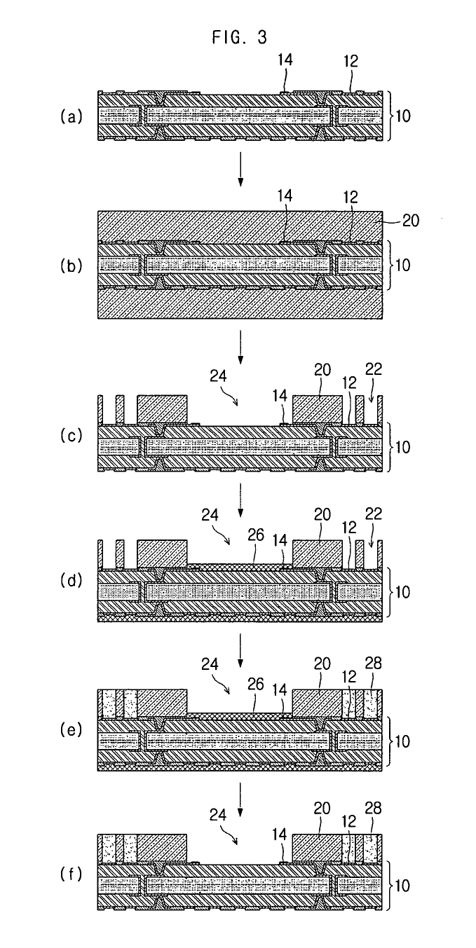

FIG. 2 is a flow chart illustrating an embodiment of manufacturing method of a bottom substrate of package on package according to the present invention, and FIG. 3 is a flow diagram illustrating an embodiment of manufacturing process of a bottom substrate of package on package according to the present invention. Referring to FIG. 3, a core board 10, solder ball pads 12, bonding pads 14, insulation layers 20, through holes 22, a cavity 24, photoresist 26, and metallic layers 28 are illustrated.

According to the present embodiment, in order to manufacture a bottom substrate of a POP connected electrically with a top substrate by a solder ball, first, as in FIG. 3 (a), the solder ball pad 12 and the bonding pad 14 are formed on the surface of the core board 10 (100). The solder ball pad 12 and the bonding pad 14, as described above, can be formed as parts of a circuit pattern in the process of forming the circuit pattern on the surface of the core board 10.

The solder ball pad 12 is a part where a solder ball will be joined for electrical connection with a top substrate, and the bonding pad 14 is a part connected electrically with an electronic device mounted on a bottom substrate. After the circuit pattern which comprises the solder ball pad 12 and the bonding pad 14 has been formed, solder resist is spread on the surface of the core board 10, and a surface treatment process is performed on the substrate.

Next, as in FIG. 3 (b), the insulation layer 20 is laminated on the core board 10 (102). For the material of the insulation layer 20, as described above, materials such as photoresist, etc. that can be etched selectively through exposure and development and whose properties can be changed by hardening can be used.

The lamination of the insulation layer 20 can be performed by laminating a film-type insulation material, or by spreading liquid-type insulation material, etc. The insulation layer 20 plays the role of maintaining the gap between a package and a package in a POP, that is, between a bottom substrate and a top substrate, and protecting the metallic layer 28, which connects the electrical signals between packages, so that it is formed reliably.

Next, as in FIG. 3 (c), parts of the insulation layer 20 is removed by applying selective exposure, development and etching to the insulation layer 20, such that the solder ball pad 12 and the bonding pad 14 are exposed, using art work film, etc. Thus, the through hole 22 is formed in the part where the solder ball pad 12 is formed, and the bonding pad 14 is formed in the part where the cavity 24 is formed (104).

After the through hole 22 and the cavity 24 are formed by removing a part of the insulation layer 20, infrared radiation or heat is applied to the insulation layer 20 in order for the insulation layer 20 to be hardened (106). This is to prevent the insulation layer 20 from being removed in the following etching process.

Next, as in FIG. 3 (d), the photoresist 26 is spread in the space of the cavity 24 where the bonding pad 14 is exposed (108). As the bonding pad 14 is coated with the photoresist 26, it can function as a resist that prevents unnecessary plating layer parts on the bonding pad 14 in the following plating process.

Next, as in FIG. 3 (e), by supplying electricity to the circuit pattern, such as to the solder ball pad 12, etc., of the core board 10 and performing electroplating, a plating layer is plated on a part of the solder ball pad 12. Thus, the metallic layer 28, which is a plating layer, is filled inside the through hole 22, which is formed by removing the insulation layer 20 selectively (110). For the plating metal, tin, copper, etc. can be used. As such, the metallic layer 28 filled inside the through hole 22 functions as a pathway for electrical connection between the solder ball pad 12 of the core board 10 and a solder ball.

Finally, as in FIG. 3 (f), in order to coat the bonding pad 14, the photoresist 26 spread on the part of the cavity 24 is peeled and removed, whereby the manufacture of the bottom substrate of POP according to the present embodiment is completed (112). Thus, the bonding pad 14 is exposed such that an electronic device can be mounted in the space of the cavity 24.

As described in the above, the insulation layer 20 is hardened using heat or infrared rays, so that the hardened insulation layer 20 remains without being peeled during the process of removing the photoresist 26 spread in the space of the cavity 24.

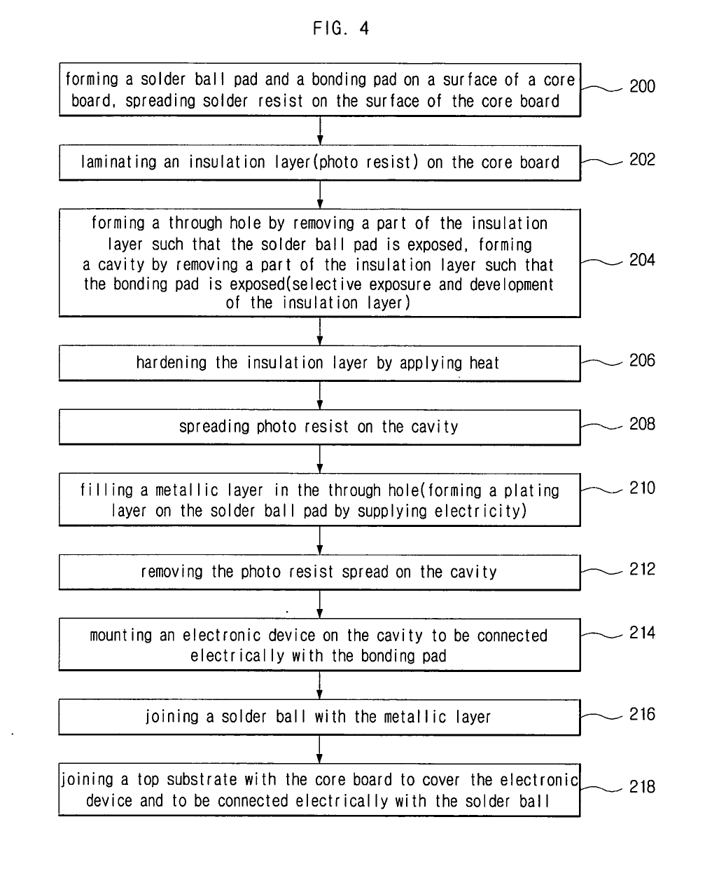

FIG. 4 is a flow chart illustrating another embodiment of manufacturing method of a bottom substrate of package on package according to the present invention.

The above-described manufacturing method of a bottom substrate of a POP can be applied in a POP manufacturing process. That is, according to the above-described embodiment, after the bottom substrate is manufactured, the electronic device may be mounted and a top substrate is joined with a solder ball interposed, to manufacture a multi stack POP.

First, the solder ball pad 12 and the bonding pad 14 are formed on the surface of the core board 10 (200). The solder ball pad 12 and the bonding pad 14, as described above, can be formed as parts of a circuit pattern in the process of forming the circuit pattern on the surface of the core board 10. After the circuit pattern comprising the solder ball pad 12 and the bonding pad 14 is formed, solder resist is spread on the surface of the core board 10, and a surface treatment process is performed on the substrate.

Next, the insulation layer 20 is laminated on the core board 10 (202). For the material of the insulation layer 20, as described above, materials such as photoresist, etc. that can be etched selectively through exposure and development and whose properties can be changed by hardening can be used. The insulation layer 20 plays the role of maintaining the gap between a package and a package in a POP, that is, between a bottom substrate and a top substrate, and protecting the metallic layer 28, which connects the electrical signals between packages, so that it is formed reliably.

Next, a part of the insulation layer 20 is removed by selective exposure, development and etching of the insulation layer 20 such that the solder ball pad 12 and the bonding pad 14 are exposed. Thus, the through hole 22 is formed in the part where the solder ball pad 12 is formed, and the cavity 24 is formed in the part where the bonding pad 14 is formed (204).

After the through hole 22 and the cavity 24 are formed by removing a part of the insulation layer 20, infrared radiation or heat is applied to the insulation layer 20 in order for the insulation layer 20 to be hardened (206). This is to prevent the insulation layer 20 from being removed in the following etching process.

Next, the photoresist 26 is spread in the space of the cavity 24 where the bonding pad 14 is exposed (208). As the bonding pad 14 is coated with the photoresist 26, it can function as a resist that prevents unnecessary plating layer parts on the bonding pad 14 in the following plating process.

Next, by supplying electricity to the circuit pattern, such as to the solder ball pad 12, etc. of the core board 10 and performing electroplating, a plating layer is plated on a part of the solder ball pad 12. Thus, the metallic layer 28, which is a plating layer, is filled inside the through hole 22, which is formed by removing the insulation layer 20 selectively (210). The metallic layer 28 filled inside the through hole 22 plays the role of a pathway for electrical connection between the solder ball pad 12 of the core board 10 and a solder ball.

Next, in order to coat the bonding pad 14, the photoresist 26 spread on the part of the cavity 24 is peeled and removed, whereby a bottom substrate is manufactured. Thus, the bonding pad 14 is exposed such that an electronic device can be mounted in the space of the cavity 24. Because the insulation layer 20 is hardened by applying heat or infrared rays, the hardened insulation layer 20 remains without being peeled, during the process of removing the photoresist 26 spread in the space of the cavity 24.

Next, an electronic device is mounted in the cavity 24 such that the electronic device is connected electrically with the bonding pad 14 (214), a solder ball is joined with the metallic layer 28 filled in the through hole 22 (216), and then a top substrate is laminate to be connected electrically with the solder ball (218). Another electronic device may be mounted on the top substrate, in which case the package having an electronic device mounted on a top substrate is stacked on the package having an electronic device mounted on a bottom substrate, whereby the manufacture of a POP is completed.

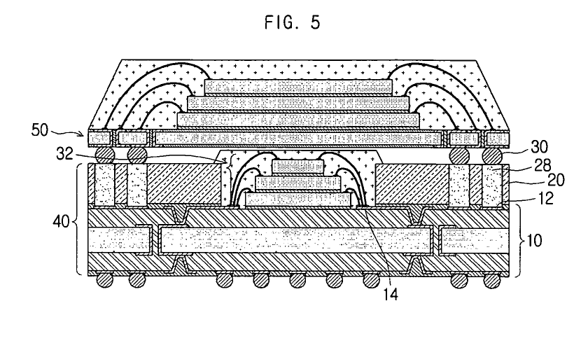

FIG. 5 is a cross-sectional view illustrating an embodiment of a package on package according to the present invention. Referring to FIG. 5, a core board 10, solder ball pads 12, bonding pads 14, an insulation layer 20, a metallic layer 28, solder balls 30, an electronic device 32, a bottom substrate 40, and a top substrate 50 are illustrated.

In the POP manufactured according to the POP manufacturing method described above, the insulation layer 20 is laminated on the bottom substrate 40, and the through hole 22 and the cavity 24 are formed, so that the sufficient gaps are ensured without increasing the size of the solder balls 30, to allow a structure by which a multi-stack can be realized.

That is, in the structure of the POP according to the present embodiment, the electronic device 32 is mounted in the cavity 24 of the bottom substrate 40 described in FIG. 1 to be electrically connected with the bonding pad 14, the solder ball 30 is joined with the metallic layer 28 filled in the through hole 22, and then the top substrate 50 with the electronic device 32 mounted is stacked on to be electrically connected with the solder ball 30.

In the structure of the bottom substrate 40, as described above, a circuit pattern comprising the solder ball pad 12 and the bonding pad 14 is formed on the surface of the core board 10, the insulation layer 20 is laminated, the through hole 22 and the cavity 24 are formed by removing parts of the insulation layer 20 such that the solder ball pad 12 and the bonding pad 14 are exposed, and then the electrical pathway is realized between the solder ball 30 and the solder ball pad 12 by filling the plating layer in the through hole 22.

In order for the insulation layer 20 to acquire the gap between packages of a POP, that is, between the bottom substrate 40 and the top substrate 50, it is preferable to use materials that can be removed selectively for forming the through hole 22 and the cavity 24, and that are not removed together in the process of removing the photoresist 26 spread in the cavity 24.

For example, in the case that photoresist is laminated on the core board 10 as the insulation layer 20 according to the present embodiment, after forming the through hole 22 and the cavity 24 through exposure, development and etching, it may be hardened by the application of heat or infrared rays, etc., so as not to be removed in the following etching process.

According to certain aspects of the invention as set forth above, the number of ICs mounted on a bottom substrate can be increased without increasing the size of the solder balls, the size and pitch of the solder balls can be made smaller by controlling the thickness of the insulation layer laminated on the bottom substrate, whereby more signal transmission is possible between a top substrate and a bottom substrate.

Also, the gap between packages can be easily controlled by controlling the thickness of the photoresist, which is an insulation material laminated on a bottom substrate, whereby more electronic devices can be stacked and mounted on the bottom substrate.

While the present invention has been described with reference to particular embodiments, it is to be appreciated that various changes and modifications may be made by those skilled in the art without departing from the spirit and scope of the present invention, as defined by the appended claims and their equivalents.

What is claimed is:

1. A method of manufacturing a bottom substrate of a package on package connected electrically with a top substrate by a solder ball, the method comprising:
forming a solder ball pad on the surface of a core board in correspondence with a location of the solder ball;
laminating an insulation layer on the core board;
forming a through hole by removing a part of the insulation layer such that the solder ball pad is exposed; and
filling a metallic layer in the through hole.

2. The method of claim 1, wherein the forming the solder ball pad further comprises spreading solder resist on the surface of the core board.

3. The method of claim 1, wherein an electronic device is mounted on the bottom substrate, the forming the solder ball pad comprises forming a bonding pad connected electrically with the electronic device on the surface of the core board, and the forming the through hole comprises forming a cavity by removing a part of the insulation layer such that the bonding pad is exposed.

4. The method of claim 3, wherein the insulation layer comprises photoresist, and the forming the through hole comprises selective exposure and development of the insulation layer.

5. The method of claim 4, further comprising:
hardening the insulation layer by applying heat,
between the forming the through hole and the filling.

6. The method of claim 5, further comprising spreading photoresist on the cavity between the hardening and the filling.

7. The method of claim 6, wherein the filling is performed by forming a plating layer on the solder ball pad by supplying electricity.

8. The method of claim 7, further comprising removing the photoresist spread on the cavity after the filling.

9. A method of manufacturing a package on package, the method comprising:
forming a solder ball pad and a bonding pad on a surface of a core board;
laminating an insulation layer on the core board;
forming a through hole by removing a part of the insulation layer such that the solder ball pad is exposed, and forming a cavity by removing a part of the insulation layer such that the bonding pad is exposed;
filling a metallic layer in the through hole;
mounting an electronic device on the cavity to be connected electrically with the bonding pad;
joining a solder ball with the metallic layer; and
joining a top substrate with the core board to cover the electronic device and to be connected electrically with the solder ball.

10. The method of claim 9, wherein the forming the solder ball comprises spreading solder resist on the surface of the core board.

11. The method of claim 9, wherein the insulation layer comprises photoresist, and the forming the through hole comprises selective exposure and development of the insulation layer.

12. The method of claim 11, further comprising:
hardening the insulation layer by applying heat,
between the forming the through hole and the filling.

13. The method of claim 12, further comprising spreading photoresist on the cavity between the hardening and the filling.

14. The method of claim 13, wherein the filling is performed by forming a plating layer on the solder ball pad by supplying electricity.

15. The method of claim 14, further comprising removing the photoresist spread on the cavity between the filling and the mounting.
